(19) United States
(12) Patent Application Publication
(10) Pub. No.: US 2013/0112943 A1
(43) Pub. Date: May 9, 2013

(54) SEMICONDUCTOR LIGHT EMITTING DEVICE

(71) Applicants: Akira TANAKA, Kanagawa-ken (JP); Yoko MOTOJIMA, Kanagawa-ken (JP)

(72) Inventors: Akira TANAKA, Kanagawa-ken (JP); Yoko MOTOJIMA, Kanagawa-ken (JP)

(73) Assignee: Kabushiki Kaisha Toshiba, Tokyo (JP)

(21) Appl. No.: 13/595,755

(22) Filed: Aug. 27, 2012

(30) Foreign Application Priority Data
Nov. 9, 2011 (JP) P2011-245023

(51) Int. Cl. H01L 33/04

(52) U.S. Cl. 257/13; 257/E33.008

(57) ABSTRACT

According to one embodiment, in a semiconductor light emitting device, a light emitting layer is partially provided on a first semiconductor layer of a first conductivity type, and has a multiple quantum well structure made by alternately laminating well layers having a first impurity concentration of the first conductivity type and barrier layers having a second impurity concentration of the first conductivity type higher than the first impurity concentration. A second semiconductor layer of a second conductivity type is provided on the light emitting layer, and has a single composition and uniform bandgap. A first distance between a first electrode provided on the first semiconductor layer and a second electrode provided on the second semiconductor layer in a direction parallel to the light emitting layer is larger than a second distance between the first electrode and the second electrode in a direction perpendicular to the light emitting layer.

### CROSS REFERENCE TO RELATED APPLICATION

This application is based upon and claims the benefit of priority from the prior Japanese Patent Application No. 2011-245023, filed Nov. 9, 2011, the entire contents of which are incorporated herein by reference.

### FIELD

Embodiments described herein relate generally to a semiconductor light emitting device.

### BACKGROUND

In the past, there is a nitride semiconductor light emitting device which includes a light emitting layer having a multiple quantum well structure made by alternately laminating well layers and barrier layers having an N-type impurity concentration higher than that of the well layers, and a P-type AlGaN overflow prevention layer interposed between the light emitting layer and a P-type clad layer.

The barrier layers which have a wide bandgap and a high N-type impurity concentration supply electron to the well layers which have a narrow bandgap. The P-type AlGaN overflow prevention layer forms a barrier in a conduction band side, and prevents the electron from overflowing from the light emitting layer. Therefore, an electron density within the well layers is increased.

However, since the P-type AlGaN overflow prevention layer has a wide bandgap, there is a problem in that a relatively low barrier in a valence band side is also formed.

In a case where a P side electrode and an N side electrode are greatly separated in a direction parallel to the light emitting layer than a direction perpendicular to the light emitting layer, the power which makes career move in the direction perpendicular to the light emitting layer becomes weak.

As a result, it becomes difficult that hole with heavy mass gets over the barrier in the valence band side formed of the P-type AlGaN overflow prevention layer. Since the hole is not sufficiently supplied within the well layers, a sufficient hole density is not obtained.

Consequently, since the hole runs short to the electron within the well layer, it becomes impossible that a radiative recombination of the electron and the hole is sufficiently performed, so that there is a problem in that a high luminous efficiency is not obtained.

### BRIEF DESCRIPTION OF THE DRAWINGS

FIGS. 1A and 1B are views illustrating a semiconductor light emitting device according to a first embodiment;

FIG. 2 is a cross-sectional view illustrating the main portion of the semiconductor light emitting device according to the first embodiment;

FIG. 3 is a cross-sectional view illustrating a semiconductor light emitting device of a comparative example according to the first embodiment;

FIGS. 4A and 4B are diagrams illustrating the energy band of the semiconductor light emitting device in comparison with that of the semiconductor light emitting device of the comparative example according to the first embodiment;

FIGS. 5A and 5B are views illustrating a carrier flow pass of the semiconductor light emitting device in comparison with that of the semiconductor light emitting device of the comparative example according to the first embodiment;

FIGS. 6A and 6B are graphs illustrating the characteristics of the semiconductor light emitting device in comparison with that of the semiconductor light emitting device of the comparative example according to the first embodiment;

FIGS. 7A to 7C are cross-sectional views illustrating the steps of manufacturing the semiconductor light emitting device in sequential order according to the first embodiment;

FIG. 8 is a cross-sectional view illustrating another semiconductor light emitting device according to the first embodiment;

FIGS. 9A and 9B are views illustrating a semiconductor light emitting device according to a second embodiment;

FIGS. 10A and 10B are cross-sectional views illustrating the steps of manufacturing the semiconductor light emitting device in sequential order according to the second embodiment;

FIG. 11 is a cross-sectional view illustrating the step of manufacturing the semiconductor light emitting device according to the second embodiment;

### DETAILED DESCRIPTION

According to one embodiment, in a semiconductor light emitting device, a first semiconductor layer has a first conductivity type. a light emitting layer is partially provided on the first semiconductor layer, and has a multiple quantum well structure made by alternately laminating well layers having a first impurity concentration of the first conductivity type and barrier layers having a second impurity concentration of the first conductivity type higher than the first impurity concentration. A second semiconductor layer of a second conductivity type is provided on the light emitting layer, and has a single composition and substantially a uniform bandgap. A first electrode is provided on the first semiconductor layer. A second electrode is provided on the second semiconductor layer. A first distance between the first electrode and the second electrode in a direction parallel to the light emitting layer is larger than a second distance between the first electrode and the second electrode in a direction perpendicular to the light emitting layer.

Hereinafter, embodiments will be described with reference to the drawings. In the drawings, same reference characters denote the same or similar portions.

### First Embodiment

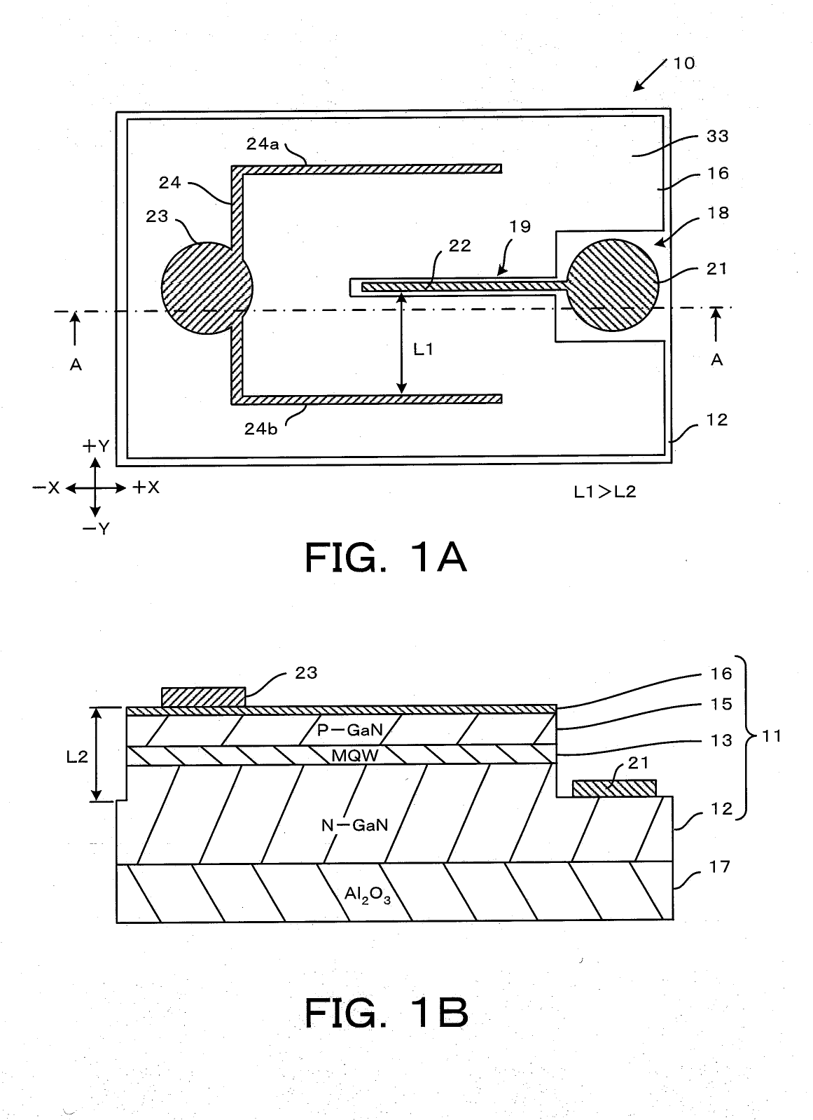

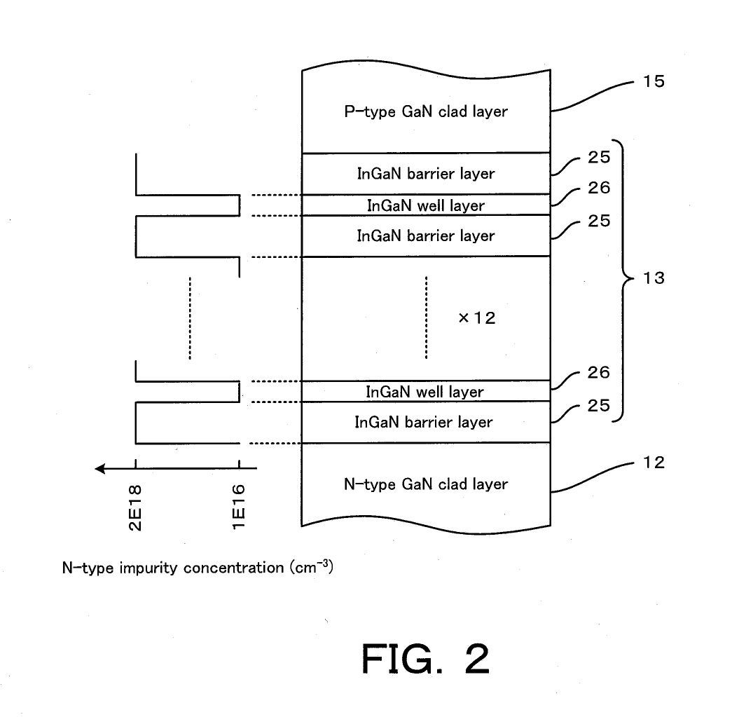

A semiconductor light emitting device of a first embodiment will be described with reference to FIGS. 1A to 2. FIGS. 1A and 1B are views illustrating the semiconductor light emitting device of the first embodiment. FIG. 1A is a top view illustrating the semiconductor light emitting device. FIG. 1B is a cross-sectional view taken along line A-A of FIG. 1A and viewed in the direction of the arrows A in FIG. 1A. FIG. 2 is a cross-sectional view illustrating the enlarged main portion of the semiconductor light emitting device. The semiconductor light emitting device of the first embodiment is a blue LED (Light Emitting Diode) made by a nitride semiconductor.

As shown in FIGS. 1A to 2, in the semiconductor light emitting device 10 of the first embodiment, a semiconductor laminated body 11 is a nitride semiconductor laminated body having an N-type GaN clad layer 12, i.e., a first semiconductor layer of a first conductivity type, a light emitting layer 13 having a multiple quantum well (MQW) structure, a P-type GaN clad layer 15, i.e., a second semiconductor layer of a second conductivity type, and a P-type GaN contact layer 16.

The semiconductor laminated body 11 is formed on a substrate 17 such as a sapphire substrate which is transparent to a light emitted by the light emitting layer 13.

The semiconductor laminated body 11 includes a cutout unit 18 and an indentation unit 19. The cutout unit 18 is made by cutting out one end side in a rectangular shape so that a portion of the N-type GaN clad layer 12 is exposed. The indentation unit 19 extends in a first direction from the cutout unit 18 to the other end side (−X direction in the figure).

A first pad electrode 21 and a first thin wire electrode 22 which are a first electrode are provided on the N-type GaN clad layer 12. The first pad electrode 21 is provided in the cutout unit 18. The first thin wire electrode 22 is provided from the first pad electrode 21 along the indentation unit 19.

The first pad electrode 21 and the first thin wire electrode 22 are laminated films including titanium (Ti)/platinum (pt)/gold (Au) capable of an ohmic contact to the N-type GaN layer, for example.

A second pad electrode 23 and a second thin wire electrode 24 which are a second electrode are provided on the P-type GaN contact layer 16. The second pad electrode 23 is provided to the other end side. The second thin wire electrode 24 is provided from the second pad electrode 23 so as to enclose the first thin wire electrode 22.

The second thin wire electrode 24 includes a wire 24a and a wire 24b extending from the second pad electrode 23 in +/−Y directions and bending and extending in +X direction.

The second pad electrode 23 and the second thin wire electrode 24 are gold (Au) film capable of an ohmic contact to the P-type GaN layer, for example.

The first thin wire electrode 22 and the second thin wire electrode 24 are provided in order to spread a current to the periphery of the semiconductor light emitting device 10. The distance between the first thin wire electrode 22 and the second thin wire electrode 24 in a direction parallel to the light emitting layer 13 is set at L1 (a first distance). The distance between the first thin wire electrode 22 and the second thin wire electrode 24 in a direction perpendicular to the light emitting layer 13 is set at L2 (a second distance). The first distance L1 is sufficiently larger than the second distance L2.

The distance L1 equal to or above at least several micrometers is required when an accuracy of etching or mask alignment in the manufacturing process of a semiconductor light emitting device is taken into consideration. Furthermore, the distance L1 equal to or above several tens of micrometers is required in order to spread the current.

On the other hand, the distance L2 is the thickness from P-type GaN contact layer 16 to the upper surface of the exposed N-type GaN clad layer 12 (equal to or below 1 μm).

The N-type GaN clad layer 12 has a thickness of approximately 4 μm and an N-type impurity concentration of approximately 1E19 cm⁻³, for example. The P-type GaN clad layer 15 has a thickness of approximately 100 nm and a P-type impurity concentration of approximately 1E20 cm⁻³, for example. The P-type GaN contact layer 16 has a thickness of approximately 5 nm and a P-type impurity concentration of approximately 1E21 cm⁻³, for example.

FIG. 2 is a cross-sectional view illustrating the light emitting layer 13. As shown in FIG. 2, the light emitting layer 13 is made by alternately laminating InGaN well layers 26 and InGaN barrier layers 25, for example. Twelve sets of InGaN well layers 26 and InGaN barrier layers 25 are formed, for example. The uppermost surface of the light emitting layer 13 is the InGaN barrier layer 25.

The InGaN barrier layer 25 has an In composition ratio of 0.05, a thickness of 10 nm and an N-type impurity concentration (a second impurity concentration) of approximately 2E18 cm⁻³, for example. The InGaN well layer 26 has an In composition ratio of 0.2, a thickness of 2.5 nm and an N-type impurity concentration (a first impurity concentration) of not more than 1E16 cm⁻³, for example.

The light emitting layer 13 has a so-called modulation doping structure. The InGaN barrier layer 25 in which a bandgap is wide is highly doped with silicon (Si) as an N-type impurity. The InGaN well layer 26 in which a bandgap is narrow is undoped.

In the modulation doping structure, a region where the amount of doping of impurities is high and a region where the amount of doping of impurities is low are intentionally formed in a semiconductor device. A discontinuity of an energy level generates at an interface between semiconductor layers from which bandgaps differ, and electron is collected on the layer in which the bandgap is narrow.

When only the semiconductor layer in which the bandgap is wide is doped with the N-type impurity to supply free electron and the semiconductor layer in which the bandgap is narrow is undoped, the free electron is supplied to the semiconductor layer in which the bandgap is narrow from the semiconductor layer in which the bandgap is wide, and the free electron can be prevented from scattering by impurities in the semiconductor layer in which the bandgap is narrow.

By applying a voltage between the first pad electrode 21 and the second pad electrode 23, carrier injected into the light emitting layer 13 is recombined, and light having a peak wavelength of approximately 450 nm is emitted, for example.

the semiconductor light emitting device 10 is configured in such a manner that the modulation doping structure of the light emitting layer 13 makes the electron density in the InGaN well layer 26 increase and makes the electron move easily in the direction parallel to the InGaN well layer 26. Furthermore, the semiconductor light emitting device 10 is configured in such a manner that a uniformity of the bandgap of the second semiconductor prevents an unnecessary barrier from generating in the valence-band side.

As a result, the electron becomes hard to overflow and the hole with heavy mass becomes easy to supply within the InGaN well layer 26.

Therefore, in a case where the first thin wire electrode 22 and the second thin wire electrode 24 are greatly separated in X-Y plane, sufficient electron density and sufficient hole density are obtained, so that the radiative recombination of the carrier can be performed easily.

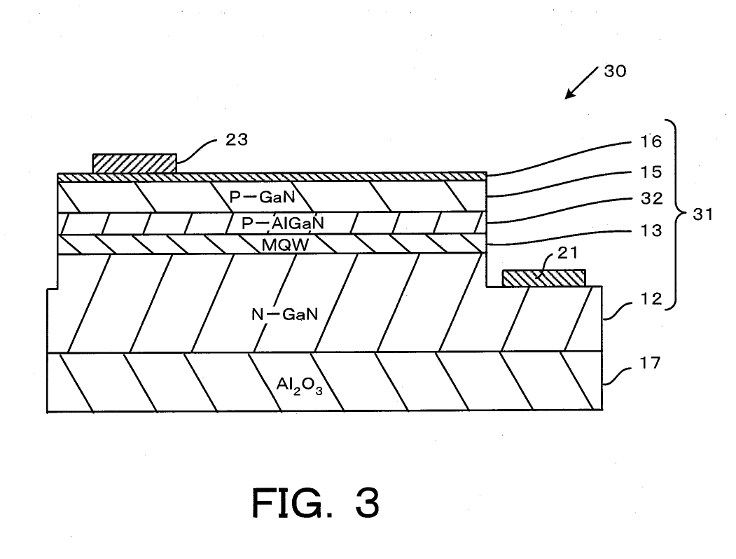

An operation of the semiconductor light emitting device 10 of the first embodiment is explained in comparison with a semiconductor light emitting device of a comparative example. FIG. 3 is a cross-sectional view illustrating the semiconductor light emitting device of the comparative example.

As shown in FIG. 3, in the semiconductor light emitting device of the comparative example, a semiconductor laminated body 31 includes a P-type AlGaN overflow prevention layer 32 interposed with the light emitting layer 13 and the P-type GaN clad layer 15. The P-type AlGaN overflow prevention layer 32 has an Al composition ratio of 0.15, a thickness of 5 nm and a P-type impurity concentration of approximately 1E20 cm⁻³, for example.

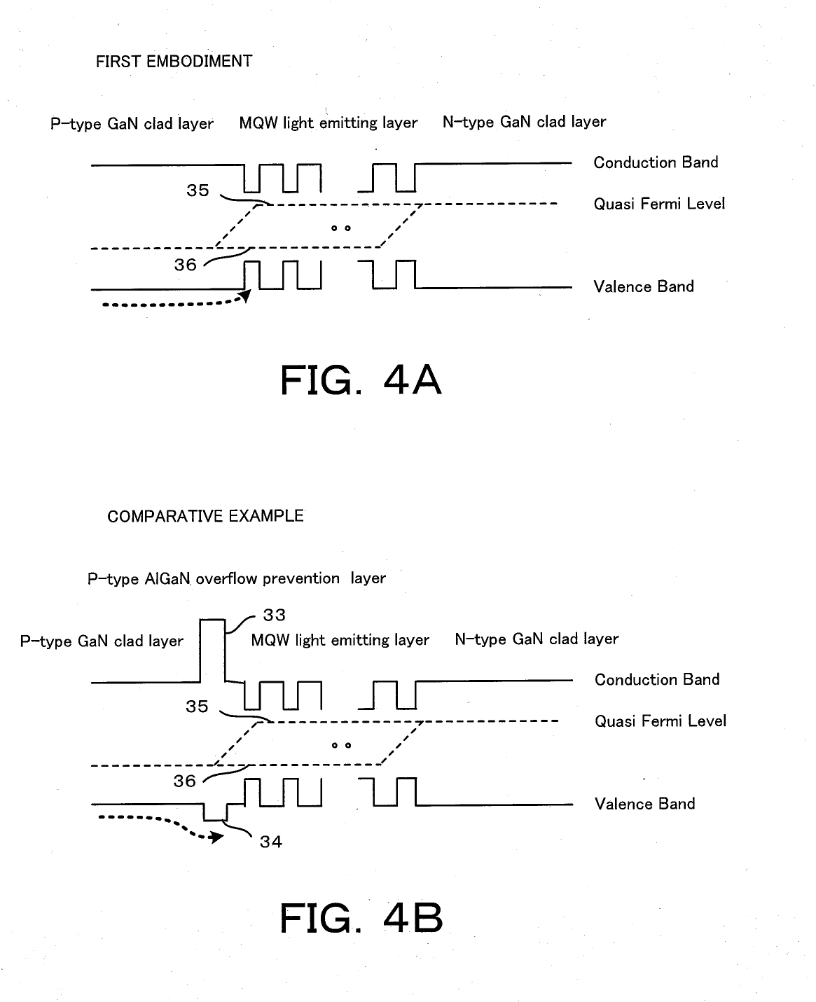

FIGS. 4A and 4B are diagrams illustrating the energy band of the semiconductor light emitting device 10 in comparison with that of the semiconductor light emitting device 30 of the comparative example. FIG. 4A is the diagram illustrating the energy band of the semiconductor light emitting device 10 of the first embodiment. FIG. 4B is the diagram illustrating the energy band of the semiconductor light emitting device 30 of the comparative example.

As shown in FIG. 4B, since the semiconductor light emitting device 30 of the comparative example has the P-type AlGaN overflow prevention layer 32, not only a high barrier 33 in the conduction band but also an unnecessary, though low, barrier 34 in the valence band are generated.

By applying a voltage between the first pad electrode 21 and the second pad electrode 23, since the electron density and the hole density are increased more than that in a thermal equilibrium state, the thermal equilibrium state turns into a non-equilibrium state, so that two quasi Fermi levels 35, 36 are generated. The Fermi level is separated so that the quasi Fermi level 35 of electron approaches the conduction band and the quasi Fermi level 36 of hole approaches the valence band.

In a case where the barrier 34 is in the valence band, the hole is hard to get over the barrier 34 in the area located far from the second thin wire electrode 24, so that the recombination is performed only in the area located near the side facing to the first thin wire electrode 22 of the second thin wire electrode 24.

Since the carrier is concentrated in the side of the second thin wire electrode 24, Auger (nonradiative) recombination is easily performed but Radiative recombination is hardly performed, so that a luminous efficiency is decreased.

On the other hand, as shown in FIG. 4A, in the light emitting device 10 of the first embodiment, the barriers 33, 34 are not generated. The modulation doping structure makes the electron spread throughout the InGaN well layer 26.

Since the bandgap of the second semiconductor layer side is uniform and there is no barrier in the valence-band side, the hole is easy to go into the whole area of the InGaN well layer 26, so that the hole recombines in the whole area of the InGaN well layer 26.

Since the recombination is spread in the whole area of the InGaN well layer 26, the carrier density becomes low and the auger (nonradiative) recombination becomes less, so that the luminous efficiency is improved.

In a case where there is a lattice mismatch in the second semiconductor layer, since a barrier is generated by a stress due to piezoelectric effect even though the bandgap is uniform, it is more preferable that the depth profile of composition of the second semiconductor layer is uniform. In the first embodiment, the second semiconductor layer has the P-type GaN clad layer 15 and the P-type GaN contact layer 16, and satisfies the requirement.

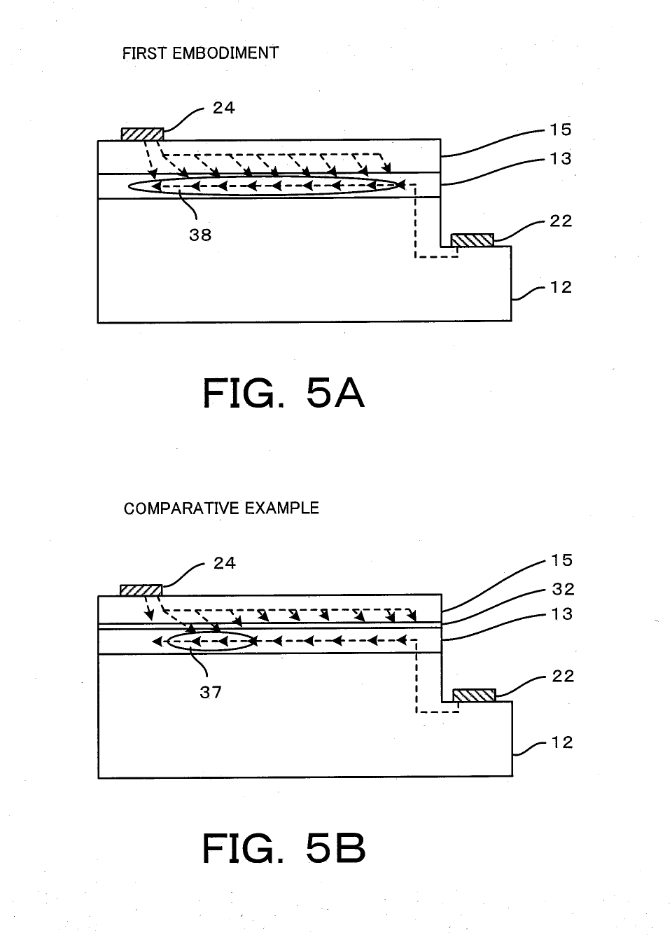

FIGS. 5A and 5B are views illustrating a carrier flow pass of the semiconductor light emitting device of the first embodiment in comparison with that of the semiconductor light emitting device of the comparative example. FIG. 5A is the view illustrating the carrier flow pass of the semiconductor light emitting device of the first embodiment. FIG. 5B is the view illustrating the carrier flow pass of the semiconductor light emitting device of the comparative example.

As shown in FIG. 5B, in the semiconductor light emitting device 30 of the comparative example, in the area located far from the second electrode 24, it becomes impossible for the hole to get over the barrier 34 in the valence band side generated by the overflow prevention layer 32, so that only near the second electrode 24, the hole recombines. A radiative recombination area 37 is stopped in the proximity of the second electrode 24.

On the other hand, as shown in FIG. 5A, in the light emitting device 10 of the first embodiment, the hole recombines up to the area located far from the second electrode 24. A radiative recombination area 38 extends up to the proximity of the first electrode 22.

In order to make high-powered with large current, it is preferable to make the carrier density low, while extending the distribution of the career (suppression of auger (nonradiative) recombination which becomes large with large current).

In summary, following requirements need to be satisfied in order to obtain a merit of the first embodiment. The requirements are as follows; 1) the first electrode and the second electrode are sufficiently separated in the horizontal direction; 2) the modulation doping structure makes the electron move in the InGaN well layer 26 in the direction parallel to the InGaN well layer 26 so that the electron becomes hard to overflow; 3) the bandgap of the second semiconductor layer is uniform so that the hole becomes easy to go into the InGaN well layer 26.

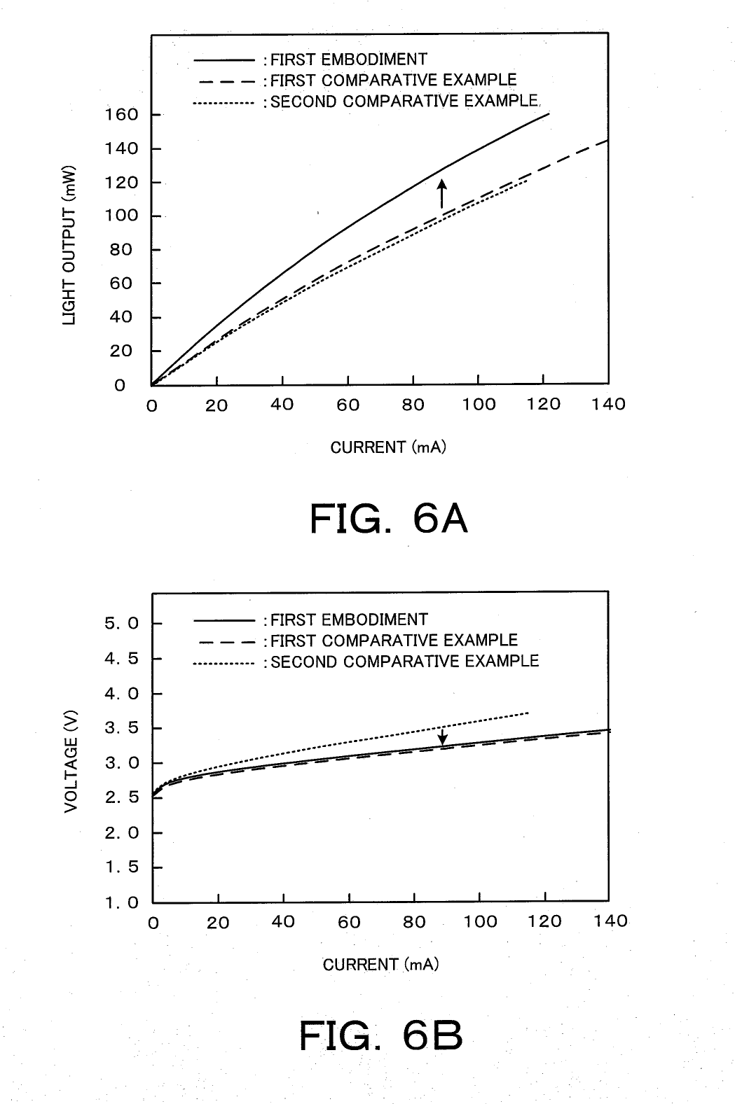

FIGS. 6A and 6B are graphs illustrating characteristics of the semiconductor light emitting device of the first embodiment in comparison with that of semiconductor light emitting devices of comparative examples. FIG. 6A is the graph illustrating a relation between current and light output. FIG. 6B is the graph illustrating a relation between current and voltage.

In FIGS. 6A and 6B, the first comparative example denotes the light emitting device 30 shown in FIG. 3 which has the light emitting layer 30 with the modulation doping structure and the P-type AlGaN overflow prevention layer 32. The second comparative example denotes a light emitting device which has a light emitting layer without the modulation doping structure and has the P-type AlGaN overflow prevention layer.

As shown in FIG. 6A, in the relation between current and light output, the difference is few although the light output of the semiconductor light emitting device of the first comparative example is little higher than that of the semiconductor light emitting device of the second comparative example. On the other hand, in the light emitting device 10 of the first embodiment, the light output about 1.3 times higher than the semiconductor light emitting devices of the first and second comparative examples is obtained with any current.

It is shown that the radiative recombination is not increased whether the electron density in the InGaN is high or low, since the injection of hole into the InGaN is suppressed by the barrier 34 which is generated in the valence band due to the P-type AlGaN overflow prevention layer 32.

On the other hand, in the light emitting device 10 of the first embodiment, it is shown that radiative recombination is increased, since the electron is enough supplied to the InGaN well layer 26 by the modulation doping structure of the light emitting layer 13 and the hole is enough supplied to the InGaN well layer 26 because the barrier 34 is not generated in the valence band.

As shown in FIG. 6B, in the relation between current and voltage, there is little difference between the light emitting device 10 of the first embodiment and the light emitting device 30 of the first comparative example. On the other hand, the light emitting device of the second comparative example has a forward voltage 1.1 times higher than the light emitting devices 10, 30 of the first embodiment and the first comparative example.

In the light emitting device of the second comparative example, it is shown that the current does not increase, since the electron is not supplied enough to a well layer of the light emitting layer without modulation doping structure.

On the other hand, in the light emitting device 30 of the first comparative example, it is shown that the voltage is decreased though the light output is not increased. The voltage is decreased since the modulation doping structure of the light emitting layer 13 sufficiently supplies the well layer with electron. The light output is not increased since Shockley-Read-Hall (SRH) recombination (nonradiative recombination) due to electron trap is increased and current due to SRH recombination is increased. Consequently, it is important that both the supply of electron and the supply of hole are increased.

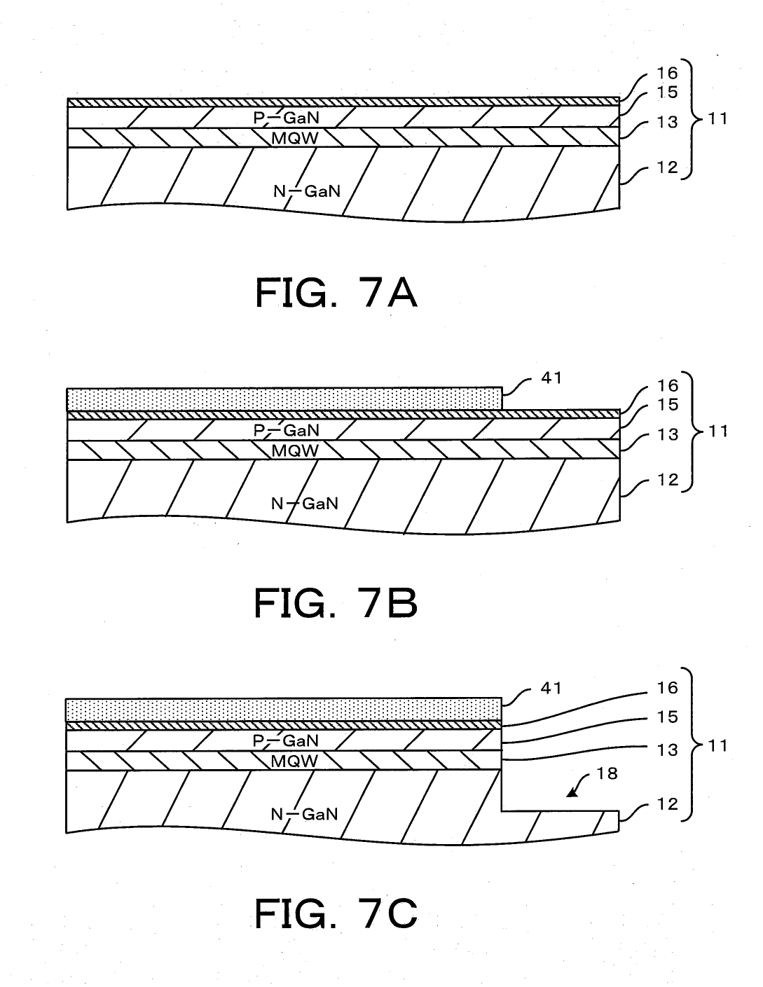

Next, a method of manufacturing the semiconductor light emitting device 10 will be explained. FIGS. 7A to 7C are cross-sectional views illustrating the steps of manufacturing the semiconductor light emitting device 10 in the sequential order.

As shown in FIG. 7A, the N-type GaN clad layer 12, the light emitting layer 13, the P-type GaN clad layer 15 and the P-type GaN contact layer 16 are epitaxially grown on the substrate 17 (not shown) for epitaxial growth in the order by a MOCVD (metal organic chemical vapor deposition) method so as to form the semiconductor laminated body 11.

The method of forming the semiconductor laminated body 11 is well known, but briefly described below. As a preliminary treatment, a sapphire substrate with a C plane of a plane direction as the substrate 17 is subjected to organic cleaning and acid cleaning, for example. The resultant sapphire substrate is contained in a reaction chamber of the MOCVD system. Thereafter, the temperature of the sapphire substrate is raised to 1100° C., for example, by high-frequency heating in a normal-pressure atmosphere of a mixed gas of a nitrogen (N₂) gas and a hydrogen (H₂) gas. Thereby, the surface of the sapphire substrate is etched in gas phase, and a natural oxide film formed on the surface of the sapphire substrate is removed.

The N-type GaN layer 12 with a thickness of 4 μm is formed by using the mixed gas of the N₂ gas and the H₂ gas as a carrier gas while supplying an ammonium (NH₃) gas and a trimethyl gallium (TMG) gas, for example, as process gases, and supplying a silane (SiH₄) gas, for example, as the N-type dopant.

The temperature of the substrate 17 is decreased to and kept at 800° C. which is lower than 1100° C., for example, while continuing supplying the NH₃ gas with the supply of the TMG gas and the SiH₄ gas stopped.

The InGaN barrier layer 25 with a thickness of 10 nm and an N-type impurity concentration of 2E18 cm⁻³, in which the In composition ratio is 0.05, is formed by using the N₂ gas as the carrier gas while supplying the NH₃ gas, the TMG gas and a trimethyl indium (TMI) gas as the process gases, SiH₄ gas as the N-type dopant gas, for example.

When the InGaN barrier layer 25 is doped with the N-type impurity in latest proximity of the interface between the InGaN barrier layer 25 and the InGaN well layer 26, the N-type impurity exudes in the InGaN well layer 26, therefore it is preferable to reduce the amount of the doping of the N-type impurity in the proximity of the interface.

The InGaN well layer 26 with a thickness of 2.5 nm, in which the In composition ratio is 0.2, is formed by stopping the supply of the SiH₄ gas and increasing the supply of the TMI gas.

The forming of the InGaN barrier layer 25 and the forming of the InGaN well layer 26 are alternately repeated 12 times, for example, while intermitting the supply of the SiH₄ gas, and increasing or decreasing the supply of the TMI gas. Thereby, the light emitting layer 13 is obtained.

The undoped GaN cap layer with a thickness of 5 nm (not shown) is formed while continuing supplying the TMG gas and the NH₃ gas with the supply of TMI stopped.

The temperature of the substrate 17 is raised to and kept at 1030° C., for example, which is higher than 800° C., in the N₂ gas atmosphere while continuing supplying the NH₃ gas with the supply of the TMG gas stopped.

the P-type GaN clad layer 15 with a thickness of 40 nm, in which the concentration of Mg is approximately 1E20 cm⁻³, is formed by using the mixed gas of the N₂ gas and the H₂ gas as the carrier gas while supplying: the NH₃ gas, the TMG gas as the process gases; and a bis(cyclopentadienyl) magnesium (Cp2Mg) gas as the P-type dopant.

The P-type GaN contact layer 16 with a thickness of approximately 10 nm, in which the concentration of Mg is approximately 1E21 cm⁻³, is formed while supplying an increased amount of Cp2Mg.

The temperature of the substrate 17 is lowered naturally with the supply of only the carrier gas continued while continuing supplying the NH₃ gas with the supply of the TMG gas stopped. The supplying of the NH₃ gas is continued until the temperature of the substrate 17 reaches 500° C. Thereby, the semiconductor laminated body 11 is formed on the substrate 17 and the P-type GaN contact layer 16 is located in the top surface.

As shown in FIG. 7B, a resist film 41 having openings corresponding to the cutout unit 18 and the indentation unit 19 is formed on the P-type GaN contact layer 16 by photolithographic method.

As shown in FIG. 7C, the layers from the P-type GaN contact layer 16 to the upper portion of the N-type GaN clad layer 12 are anisotropically etched using the resist film 41 as the mask by RIE method using a gas of chlorine system, and a portion of the N-type GaN clad layer 12 is exposed. Thereby, the cutout unit 18 and the indentation unit 19 are formed.

After the resist film 41 is removed using asher, for example, using a well-known method, the first pad electrode 21 and the first thin wire electrode 22 are formed. The first pad electrode 21 is formed on the N-type GaN layer 12 in the cutout unit 18. The first thin wire electrode 22 extends from the first pad electrode 21 along the indentation unit 19.

The second pad electrode 23 and the second thin wire electrode 24 are formed. The second pad electrode 23 is formed on the P-type GaN contact layer 16 at the other end side. The second thin wire electrode 24 extends from the second pad electrode 23 in +/−Y directions and bending and extending in +X direction. As a result, the semiconductor light emitting device 10 shown in FIGS. 1A and 1B is obtained.

As described above, in the semiconductor light emitting device 10 of the first embodiment, the light emitting layer 13 has the modulation doping structure so that the electron density is increased in the InGaN well layer 26, and the bandgap of the second semiconductor layer is uniform so that the unnecessary barrier is prevented from generating in the valence band side.

As a result, it becomes easy for the electron to move in the InGaN well layer 26, it becomes easy for the carrier to flow in the direction parallel to the InGaN well layer 26, and it becomes hard for the electron to overflow. The hole with heavy mass becomes easy to be injected into the InGaN well layer 26.

Injection efficiencies of both the electron and the hole are improved and it becomes easy for the carrier to recombine. Consequently, the light emitting device in which the luminous efficiency is improved by facilitating the supply of hole is obtained.

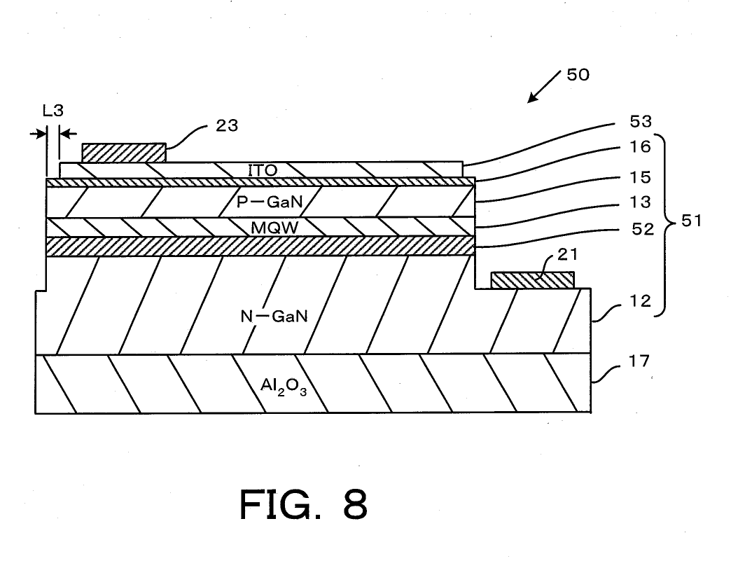

A transparent conductive film and a super lattice buffer layer may be provided to the light emitting device 10. FIG. 8 is a cross-sectional view illustrating a semiconductor light emitting device to which the transparent conductive film and the super lattice buffer layer are provided.

As shown in FIG. 8, in a semiconductor light emitting device 50, a semiconductor laminated body 51 includes a super lattice buffer layer 52 interposed between the N-type GaN contact layer 12 and the light emitting layer 13. A transparent conductive film 53 which is transparent to the light emitted from the light emitting layer 13 is provided on the P-type GaN contact layer 16.

The super lattice buffer layer 52 is made by alternately laminating InGaN well layers and InGaN barrier layers. Thirty sets of the InGaN well layer and the InGaN barrier layer are formed. The In composition of the InGaN well layer is different from that of the InGaN well layer 26 of the light emitting layer 13.

The InGaN well layer has a thickness of approximately 1 nm and an N-type impurity concentration (a third impurity concentration) of approximately 1E16 cm⁻³ or less, for example. The InGaN barrier layer has a thickness of approximately 3 nm and an N-type impurity concentration (a fourth impurity concentration) of approximately 2E18 cm⁻³, for example.

Since the super lattice buffer layer 52 prevents crystalline defects such as dislocation from propagating to the light emitting layer 13 from the N-type GaN clad layer 12, the quality of the light emitting layer 13 is improved. As a result, there is an advantage in that the luminous efficiency is improved.

Since the super lattice buffer layer 52 has the similar modulation doping structure as the light emitting layer 13, there is an advantage in that the super lattice buffer layer 52 supplies the InGaN well layer 26 of the light emitting layer 13 with electron.

The transparent conductive film 53 is an ITO (Indium Tin Oxide) film with a thickness of 0.1 to 0.2 μm, for example. The second pad electrode 23 and the thin wire electrode 24 are provided on the transparent conductive film 53. The transparent conductive film 53 makes it easy to spread current up to the periphery of the light emitting device 50.

A thicker ITO film is preferred in order to spread current. On the other hand, since the ITO film slightly absorbs light, a thinner ITO film is preferred in order to extract light. Hereinafter, the transparent conductive film is also referred to as the ITO film.

The transparent conductive film 53 is formed inside of the edge of the P-type GaN contact layer 16 by a distance L3, 10 μm, for example, in order to alleviate a surface current flowing along a side surface of the semiconductor laminated body 11. The distance L3 is preferably equal to or more than 10 times the diffusion length (in the order of 0.1 μm) of minority carrier injected into the light emitting layer 13.

Assume the P-type GaN contact layer 16 has an impurity concentration of approximately 1E21 cm⁻³ and a mobility of approximately 10 cm²/V·s, for example, the resistivity is 5E−4 Ωcm. When the thickness of the P-type GaN contact layer 16 is 5 nm, a sheet resistance of the P-type GaN contact layer 16 is approximately 1 kΩ/□.

The resistivity of the transparent conductive film 53 varies in accordance with processes and conditions, but can be 2E−4 Ωcm. The transparent conductive film 53 becomes 12Ω/□ or less even when the thickness is 0.2 μm or less at which sufficient transmittance 80% or more, for example, can be obtained.

### Second Embodiment

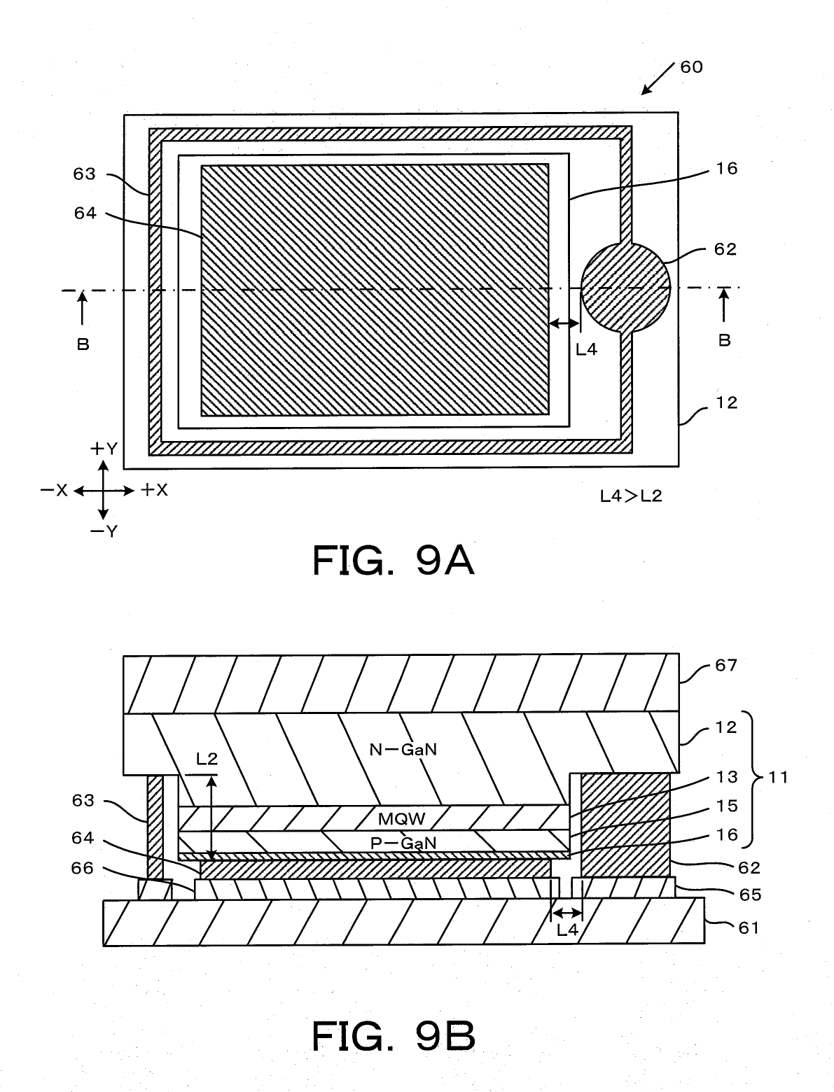

A semiconductor light emitting device of a second embodiment will be described with reference to FIGS. 9A and 9B. FIGS. 9A and 9B are views illustrating the semiconductor light emitting device of the second embodiment. FIG. 9A is a top view illustrating the semiconductor light emitting device. FIG. 9B is a cross-sectional view of the semiconductor light emitting device mounted on a substrate taken along line B-B of FIG. 9A and viewed in the direction of the arrows B in FIG. 9A.

In the second embodiment, the same portions as those in the first embodiment are denoted by the same reference numerals, and descriptions of the same portions are omitted. Only different portions will be described. The second embodiment differs from the first embodiment in that the light is extracted from the N-type GaN clad layer side.

as shown in FIGS. 9A and 9B, since the semiconductor light emitting device 60 of the second embodiment is a flip chip, the P-type GaN contact layer 16 side is mounted on a substrate 61, so that the light emitted from the light emitting layer 13 is extracted from the N-type GaN clad layer 12 side.

The periphery of the semiconductor laminated body 11 is removed so as to fully expose the periphery of the N-type GaN clad layer 12. The semiconductor laminated body 11 is a convex shape.

A first pad electrode 62 is provided in the end side of the N-type GaN clad layer 12. The first thin wire electrode 63 is provided along the periphery of the N-type GaN clad layer 12 from the first pad electrode 62 so as to enclose the P-type GaN contact layer 16. The first pad electrode 62 is a circle shape and the first thin wire electrode 63 is a shape of a picture frame so as to spread the current.

The second pad electrode 64 is provided all over on the P-type GaN contact layer 16 except the outer edge portion of the P-type GaN contact layer 16. The second pad electrode 64 is rectangle shape.

The distance between the first pad electrode 62 and the second pad electrode 64 in the direction parallel to the light emitting layer 13 is set at L4 (the first distance). The distance between the first pad electrode 62 and the second pad electrode 64 in the direction perpendicular to the light emitting layer 13 is set at L2 (the second distance). The first distance L1 is sufficiently larger than the second distance L2.

The substrate 61 is an insulating substrate, i.e., a ceramics substrate. A first substrate electrode 65 facing the first pad electrode 62 and the thin wire electrode 63 is provided on the substrate 61. A second substrate electrode 66 facing the second pad electrode 64 is provided on the substrate 61. The first substrate electrode 65 and the second substrate electrode 66 are made of AuSn alloy.

The first pad electrode 62 is placed on the first portion of the first substrate electrode 65, the first thin wire electrode 63 is placed on the second portion of the first substrate electrode 65, and the second pad electrode 64 is placed on the second substrate electrode 66, so that the semiconductor laminated body 11 and the substrate 61 are bonded each other.

By applying a voltage between the first substrate electrode 65 and the second substrate electrode 66, the carrier injected into the light emitting layer 13 is recombined, and light having a peak wavelength of approximately 450 nm is emitted, for example.

Some of the light emitted to the P-type GaN contact layer 16 side from the light emitting layer 13 is reflected with the second pad electrode 64 and extracted from the N-type GaN clad 12 side.

In the light emitting device 60 of the second embodiment, since the first pad electrode 62 and the second pad electrode 64 are sufficiently separated each other in the direction parallel to the light emitting layer 13, a luminous efficiency can be improved in the same manner as the light emitting device 10 shown in FIGS. 1A and 1B, so that a light output can be increased.

A resin 67 is provided on the N-type GaN clad layer 12 in order to extract light easily from the N-type GaN clad layer 12. When the resin 67 contains YAG fluorescent substance, white light with a high output can be obtained.

The YAG fluorescent substance can be expressed with a general formula as follows.

(RE₁₋ₓSmₓ)₃(Al_{y}Ga_{1-y})₅O₁₂:Ce

Where 0≦x≦1, 0=<y=<1, RE denotes at least one kind of elements selected from Y and Gd.

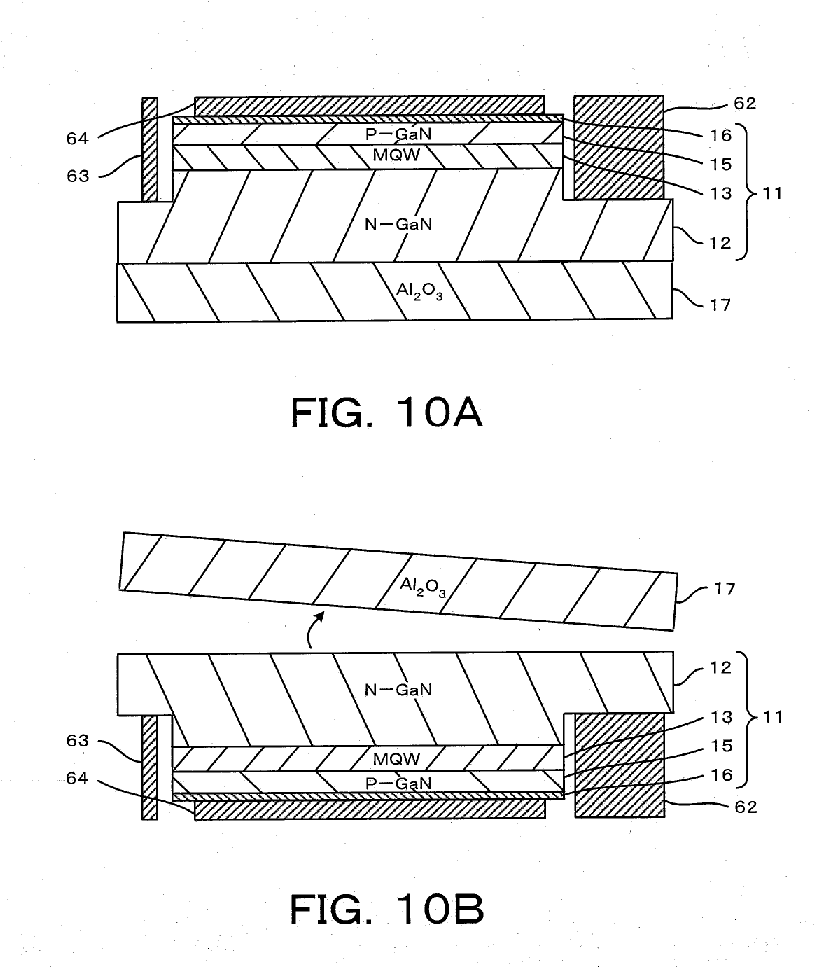

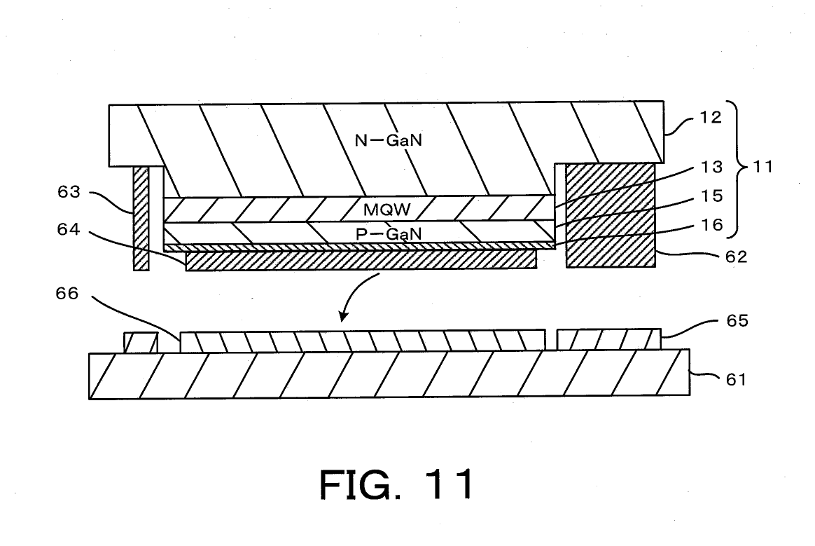

The method of manufacturing the semiconductor light emitting device 60 will be explained. FIGS. 10A to 11 are cross-sectional views illustrating the steps of manufacturing the semiconductor light emitting device 60.

As shown in FIG. 10A, in the same manner as FIGS. 7A to 7C, the semiconductor laminated body 11 is formed on the substrate 17 by the MOCVD method, the periphery of the semiconductor laminated body 11 is etching anisotropically by the RIE method using a resist film as a mask, so that the periphery of the N-type GaN clad layer 12 is fully exposed.

The first pad electrode 62 and the first thin wire electrode 63 are formed on the exposed portion of the N-type GaN clad layer 12. The second pad electrode 64 is formed on the P-type GaN contact layer 16.

As shown in FIG. 10B, the substrate 17 and the semiconductor laminated body 11 are separated by laser lift-off method. The laser lift-off method is a method for emitting high-output laser beam to partially decompose inside of a substance by heat application and separating the substance with the decomposed portion being the border.

More specifically, laser beam is emitted, so that the laser beam passes through the substrate 17 but is absorbed by the N-type GaN clad layer 12, whereby the N-type GaN clad layer 12 is dissociated, and the substrate 17 and the N-type GaN clad layer 12 are separated.

For example, the fourth harmonic wave (266 nm) of the Nd-YAG laser is emitted from the side of the substrate 17. Sapphire is transparent to the light, and therefore, the emitted light passes through the substrate 17 and is effectively absorbed by the N-type GaN clad layer 12.

The N-type GaN clad layer 12 in proximity to the interface with the substrate 17 includes many crystalline defects, and therefore, substantially all of the absorbed light is converted into heat, and the following reaction occurs.

2GaN=2Ga+N₂(g)

Accordingly, GaN is dissociated into Ga and N₂ gas.

It is appropriate that the laser beam is focused on the N-type GaN clad layer 12 in proximity to the interface with the substrate 17. The laser beam may be a continuous wave (CW) or a pulse wave (PW), but the laser beam is preferably a pulse light having a high peak output.

A Q switch laser, a mode locked laser, and the like capable of outputting ultra short pulse light in the order of picoseconds to femtoseconds are appropriate as pulse lasers having a high peak output.

The resin 67 is formed on the N-type GaN clad layer 12 which is exposed after removal of the substrate 17. The resin 67 is an epoxy resin containing the YAG fluorescence substance 40 weight % to 50 weight %, for example.

As shown in FIG. 11, the semiconductor laminated body 11 is reversed upside down, so that the first pad electrode 62 and the first thin wire electrode 63 face the first substrate electrode 65, the second pad electrode 64 faces the second substrate electrode 66, and the semiconductor laminated body 11 and the substrate 61 are placed on each other.

Thereafter, the semiconductor laminated body 11 and the substrate 61 are bonded by heating the substrate 61 to melt the gold tin alloy film. Since AuSn becomes in a molten state at approximately 300° C., the first pad electrode 62 and the first substrate electrode 65 are fused, the first thin wire electrode 63 and the first substrate electrode 65 are fused and the second pad electrode 64 and the second substrate electrode 66 are fused. Therefore, the semiconductor light emitting device 60 which is mounted on the substrate 61 shown in FIG. 9 is obtained.

As described above, in the semiconductor light emitting device 60 of the second embodiment, the P-type GaN contact layer 16 side is mounted on the substrate 61, and the light emitted from the light emitting layer 13 is extracted from the N-type GaN clad layer 12.

Also in this structure, since the first pad electrode 62 is sufficiently separated from the second pad electrode 64 in the direction parallel to the N-type GaN clad layer 12, the luminous efficiency is improved in the same manner as the semiconductor light emitting device 10 shown as FIGS. 1A and 1B, so that the light output can be increased. The semiconductor light emitting device 60 is a structure suitable for a case where the chip size is relatively large.

The descriptions have been given for the case where the second pad electrode 64 which is the gold film is used as the light reflection film. However, the light output may be increased when a silver film which has a higher reflectivity than the gold film is used as the light reflection film.

In the case where the silver film is used as the light reflection film, it is preferable that the second pad electrode 64 is a laminated film in which the silver film and the gold film are stacked. Firstly, the silver film with a thickness of approximately 300 nm and the gold film with a thickness of approximately 700 nm are formed on the P-type GaN contact layer 16 by sputtering method in the order, for example. Next, the silver film and the gold film are subjected to a heat treatment. Thereafter, the silver film which contacts the P-type GaN contact layer 16 is alloyed, and the silver film and the gold film become the second pad electrode 64 which is over-coated with the gold film and has two layers.

The over-coat of the gold film prevents beforehand the silver film from transubstantiating (oxidizing or sulfurizing) or migrating in the fabrication process. Moreover, since specific resistance of silver is lower than that of gold and thermal conductivity of silver is higher than that of gold, it is expected that an electrical property and a thermal characteristic are improved.

While certain embodiments have been described, these embodiments have been presented by way of example only, and are not intended to limit the scope of the inventions. Indeed, the novel devices described herein may be embodied in a variety of other forms; furthermore, various omissions, substitutions and changes in the form of the devices described herein may be made without departing from the spirit of the inventions. The accompanying claims and their equivalents are intended to cover such forms or modifications as would fall within the scope and spirit of the inventions.

What is claimed is:

1. Semiconductor light emitting device, comprising:
a first semiconductor layer of a first conductivity type;
a light emitting layer partially provided on the first semiconductor layer, and having a multiple quantum well structure made by alternately laminating well layers having a first impurity concentration of the first conductivity type and barrier layers having a second impurity concentration of the first conductivity type higher than the first impurity concentration;
a second semiconductor layer of a second conductivity type provided on the light emitting layer, and having a single composition and substantially uniform bandgap;
a first electrode provided on the first semiconductor layer; and
a second electrode provided on the second semiconductor layer, a first distance between the first electrode and the second electrode in a direction parallel to the light emitting layer being larger than a second distance between the first electrode and the second electrode in a direction perpendicular to the light emitting layer.

2. The semiconductor light emitting device according to claim 1, wherein the light emitting layer and the second semiconductor layer include a cutout unit provided at one end side and an indentation unit extending from the cutout unit in a first direction toward the other end side so as to expose a portion of the first semiconductor layer, the first electrode includes a first pad electrode provided on the cutout unit and a first thin wire electrode extending from the first pad electrode along the indentation unit, the second electrode includes a second pad electrode provided at the other end side, and a second thin wire electrode extending from the second pad electrode provided at the other end side in the second direction as well as in a direction opposite to the second direction and bending and extending in a direction opposite to the first direction.

3. The semiconductor light emitting device according to claim 1, wherein the first impurity concentration is equal to or less than 1E16 cm⁻³, the second impurity concentration is equal to or more than 2E18 cm⁻³.

4. The semiconductor light emitting device according to claim 1, further comprising a transparent conductive film provided on the second semiconductor layer, the second electrode being provided on the transparent conductive film.

5. The semiconductor light emitting device according to claim 3, wherein the transparent conductive film is an ITO film, a ZnO film, or a Sn₂O film.

6. The semiconductor light emitting device according to claim 3, wherein the transparent conductive film is provided inside the edge of the first semiconductor layer, the distance between the edge of the transparent conductive film and the edge of the first semiconductor layer is equal to or more than 10 times a diffusion length of minority carrier injected into the light emitting layer.

7. The semiconductor light emitting device according to claim 1, further comprising a super lattice buffer layer provided between the first semiconductor layer and the light emitting layer, the super lattice buffer layer being made by alternately laminating well layers having a different composition from the well layers, and a third impurity concentration of the first conductivity type and barrier layers having a fourth impurity concentration of the first conductivity type higher than the third impurity concentration.

8. The semiconductor light emitting device according to claim 6, wherein the third impurity concentration is equal to or lower than 1E16 cm⁻³, the fourth impurity concentration is equal to or more than 2E18 cm⁻³.

9. The semiconductor light emitting device according to claim 1, wherein the first semiconductor layer includes an N-type GaN clad layer, the second semiconductor layer includes a P-type GaN clad layer and a P-type GaN contact layer.

10. The semiconductor light emitting device according to claim 1, wherein the light emitting layer includes a Multiple Quantum Well made by alternately laminating Inₓ₁Al_{y1}Ga_{(1-x1-y1)}N well layers (0<x1<1, 0≦y1<1) and Inₓ₂Al_{y2}Ga_{(1-x2-y2)}N (0≦x2<1, 0≦y2<1, x1>x2) barrier layers.

11. A semiconductor light emitting device, comprising:
a first semiconductor layer of a first conductivity type having a central portion and a peripheral portion to enclose the central portion;
a light emitting layer provided on the central portion of the first semiconductor layer, and having a multiple quantum well structure made by alternately laminating well layers having a first impurity concentration of the first conductivity type and barrier layers having a second impurity concentration of the first conductivity type higher than the first impurity concentration;
a second semiconductor layer of a second conductivity type provided on the light emitting layer, and having a single composition and substantially uniform bandgap;
a first electrode provided on the first semiconductor layer along the peripheral portion; and
a second electrode provided on the second semiconductor layer so as to cover the second semiconductor layer.

12. The semiconductor light emitting device according to claim 11, wherein the main surface of the central portion protrudes from the main surface of the peripheral portion.

13. The semiconductor light emitting device according to claim 11, wherein the first impurity concentration is equal to or less than 1E16 cm⁻³, the second impurity concentration is equal to or more than 2E18 cm⁻³.

14. The semiconductor light emitting device according to claim 11, further comprising a super lattice buffer layer provided between the first semiconductor layer and the light emitting layer, the super lattice buffer layer being made by alternately laminating well layers having a different composition from the well layers, and a third impurity concentration of the first conductivity type and barrier layers having a fourth impurity concentration of the first conductivity type higher than the third impurity concentration.

15. The semiconductor light emitting device according to claim 14, wherein the third impurity concentration is equal to or lower than 1E16 cm⁻³, the fourth impurity concentration is equal to or more than 2E18 cm⁻³.

16. The semiconductor light emitting device according to claim 11, further comprising a resin provided on the surface of the first semiconductor layer which is opposite to the light emitting layer, and having transparency to a light emitted from the light emitting layer.

17. The semiconductor light emitting device according to claim 16, wherein the resin contains a fluorescence substance to absorb the light emitted from the light emitting layer and to emit a light with a wavelength longer than that of the light emitted from the light emitting layer.

18. The semiconductor light emitting device according to claim 11, wherein the first semiconductor layer includes an N-type GaN clad layer, the second semiconductor layer includes a P-type GaN clad layer and a P-type GaN contact layer.

19. The semiconductor light emitting device according to claim 11, wherein the light emitting layer includes a Multiple Quantum Well made by alternately laminating Inₓ₁Al_{y1}Ga_{(1-x1-y1)}N well layers (0<x1<1, 0≦y1<1) and Inₓ₂Al_{y2}Ga_{(1-x2-y2)}N (0≦x2<1, 0≦y2<1, x1>x2) barrier layers.
